(19) United States
(12) Patent Application Publication
(10) Pub. No.: US 2024/0106100 A1
(43) Pub. Date: Mar. 28, 2024

(54) ELECTROMAGNETIC FILTER ASSEMBLY FOR ATTENUATING ELECTROMAGNETIC INTERFERENCES, FEEDTHROUGH ASSEMBLY, ENCLOSURE ASSEMBLY AND VEHICLE

(71) Applicant: Volvo Car Corporation, Göteborg (SE)

(72) Inventors: Anders LASSON, Göteborg (SE); Torstensson PER, Göteborg (SE); Georgios MADEMLIS, Göteborg (SE); Kurt ERIKSSON, Göteborg (SE)

(21) Appl. No.: 18/468,367

(22) Filed: Sep. 15, 2023

(30) Foreign Application Priority Data
Sep. 22, 2022 (EP) 22197071.8

(51) Int. Cl. H01P 1/20; B60R 16/03; H02G 3/22

(52) U.S. Cl. CPC H01P 1/20; B60R 16/03; H02G 3/22

(57) ABSTRACT

An electromagnetic filter assembly for attenuating electromagnetic interferences can comprise a base plate comprising a first opening configured to be penetrated by a first conductor from which an electromagnetic interference at least partially originates, wherein the base plate comprises an electrically non-conductive carrier layer, an electrically conductive first layer section, and an electrically conductive second layer section, wherein the first layer section comprises a shielding interface configured to connect the first layer section to a shielding in an electrically conductive manner, wherein the second layer section comprises a first conductor interface configured to connect the second layer section to the first conductor in an electrically conductive manner, and wherein the first layer section and the second layer section are capacitively coupled via at least two discrete capacitor elements.

### CROSS-REFERENCE TO RELATED APPLICATIONS

This application claims the benefit of and priority to pending EP patent application serial number 22197071.8, filed Sep. 22, 2022, and entitled “ELECTROMAGNETIC FILTER ASSEMBLY FOR ATTENUATING ELECTROMAGNETIC INTERFERENCES, FEEDTRHOUGH ASSEMBLY, ENCLOSURE ASSEMBLY AND VEHICLE,” the entirety of which is hereby incorporated by reference herein.

### TECHNICAL FIELD

The present disclosure relates to assemblies for attenuating electromagnetic interferences.

### BACKGROUND

Electromagnetic filter assemblies can be used to attenuate electromagnetic interferences. A specific field of use of such electromagnetic filter assemblies are feedthrough assemblies, i.e., components or groups of components that are configured to transfer an electric conductor from one side of a wall to an opposite side of a wall. In the present context, a feedthrough assembly is to be understood as a feedthrough assembly for an electric conductor such as an electric cable or an electric bus bar. The wall may be a wall of an enclosure.

In these kind of applications, the electromagnetic filter assembly is used in order to block electromagnetic interferences that are generated on one side of the wall from reaching the other side of the wall. In a case in which the enclosure assembly houses an electric device, the electromagnetic filter assembly being used in conjunction with a feedthrough assembly solves two problems. First, electromagnetic interferences originating from the electric device inside the enclosure assembly are blocked from reaching an environment or an outside of the enclosure assembly where other electric installations could be disturbed. Second, electromagnetic interferences being present in the environment of the enclosure assembly do not interfere with or disturb the operation of the electric device being arranged inside the enclosure assembly.

For conventional electromagnetic filter assemblies, it is common to find a trade-off between production costs, compactness, and filter performance. Usually, filter assemblies having a high filter performance come together with comparatively high production costs and low compactness.

### SUMMARY

It is an objective of the present invention to solve or at least reduce this conflict of objectives. Thus, an electromagnetic filter assembly shall be provided which is compact and may be produced in a cost-efficient manner. At the same time, the electromagnetic filter assembly shall have a good filter performance.

The problem is at least partially solved or alleviated by the subject matter of the independent claims of the present disclosure, wherein further examples are incorporated in the dependent claims.

The present disclosure relates to an electromagnetic filter assembly for attenuating electromagnetic interferences.

Moreover, the present disclosure is directed to a feedthrough assembly and an enclosure assembly for at least one electric component, comprising such an electromagnetic filter assembly.

Additionally, the present disclosure is directed to a vehicle comprising such an enclosure assembly.

According to a first aspect, there is provided an electromagnetic filter assembly for attenuating electromagnetic interferences. The filter assembly comprises a base plate having a first opening being configured to be penetrated by a first conductor from which the electromagnetic interference at least partially originates. The base plate comprises an electrically non-conductive carrier layer, an electrically conductive first layer section and an electrically conductive second layer section. The first layer section comprises a shielding interface configured to connect the first layer section to a shielding in an electrically conductive manner. The second layer section comprises a first conductor interface configured to connect the second layer section to the first conductor in an electrically conductive manner. The first layer section and the second layer section are capacitively coupled via at least two discrete capacitor elements. The fact that the first opening is configured to be penetrated by a first conductor means that a first conductor may extend through the first opening such that a first end of the first conductor is located on one side of the opening and an opposite end of the first conductor is located on an opposite side of the opening. Additionally, it has to be noted that the first layer section and the second layer section are electrically isolated from one another, i.e., they are not conductively coupled within the base plate. Moreover, the first layer section and the second layer section may be arranged directly or indirectly on the carrier layer. In this context, the terms “first” and “second” are used in order to facilitate the explanation of the electromagnetic filter assembly. These terms do not imply any number of layer sections. A discrete capacitor element may be formed by any electric component that can provide a capacitance, e.g., a classic capacitor, a varistor or a zener diode. The capacitor element may be formed as a surface mounted device (SMD) or as a through-hole component. Being discrete means that the capacitor element has a clear border with respect to its environment. Moreover, it is generally formed as a single body or a group of fixedly connected bodies. Consequently, using the electromagnetic filter assembly, the first conductor, from which the electromagnetic interference at least partially originates, may be connected to a shielding via the at least two capacitor elements. Thus, electromagnetic interferences originating from the first conductor may be attenuated in an effective manner. Moreover, due to the fact that a base plate as described above and discrete capacitor elements are compact, the electromagnetic filter assembly as a whole is compact. Furthermore, base plates may be produced in a simple and cost-efficient manner. The same is true for the assembly of discrete capacitor elements thereon. Altogether, the electromagnetic filter assembly may be manufactured in a cost-efficient manner.

In the present context, a shielding to which the first layer section may be connected in an electrically conductive manner is to be understood as an electric or electromagnetic shielding. The shielding may have any electric potential, e.g., zero volts or 12 volts. In case the shielding is at a potential of zero volts, the shielding is at ground potential. In this case, the shielding and the ground may fall together such that the shielding is formed by a ground element.

In an example, the at least two capacitor elements have the same electric capacitance.

In an example, the base plate is formed as a printed circuit board. Such base plates may be produced in an especially cost-efficient manner. Moreover, the first layer section and the second layer section may be integrated into the base plate in a compact manner. The printed circuit board may be at least partially rigid and/or at least partially flexible. Of course, the printed circuit board may also be entirely rigid or entirely flexible. The printed circuit board may also be formed as a printed circuit board tape.

It is noted that the electromagnetic filter assembly according to the present disclosure may be used for filtering interferences resulting from a conductor carrying direct current (DC), alternating current (AC) and any other type of current from which an electromagnetic interference may originate.

An electromagnetic filter assembly according to the present disclosure may be called an electromagnetic interference filter or EMI filter.

In an example, the electromagnetic filter assembly according to the present disclosure is not configured to transmit power.

In an example, the first layer section and the second layer section are arranged in a common plane. Consequently, during production, the first layer section and the second layer section may be produced as electrically isolated parts of one conductive layer. This is comparatively simple and efficient. Moreover, this configuration of the first layer section and the second layer section render the base plate compact.

In an example, the first layer section and the second layer section are arranged at least partially opposite each other such that the first layer section and the second layer section form a capacitor. In other words, each of the first layer section and the second layer section forms an electrode of a common capacitor. In this configuration, the carrier layer may form a dielectric layer of the capacitor. This capacitor is provided in addition to the discrete capacitor elements as mentioned above. Consequently, the filtering performance is further enhanced. At the same time, the size of the electromagnetic filter assembly is not at all or just slightly increased. Additionally, the electromagnetic filter assembly may still be produced in a simple and cost-efficient manner.

In an example, the at least two discrete capacitor elements are evenly distributed around a circumference of the first opening. The at least two discrete capacitor elements may be oriented in a radial direction with respect to the first opening. Thus, in a case in which two discrete capacitor elements are provided, they are spaced by approximately 180° around the circumference of the first opening. In a case in which three capacitor elements are provided, they are spaced by approximately 120° around the circumference of the first opening. In a further case, in which four capacitor elements are provided, they are spaced by approximately 90° around the circumference of the first opening. In other words, the capacitor elements are pair-wise opposite one another, wherein the pairs are arranged orthogonally to one another. The even distribution of the capacitor elements leads to a symmetric arrangement of the capacitor elements around the first opening. Such an arrangement further enhances the filter performance. The use of additional capacitor elements increases the total capacitance and thus also improves the filter performance.

In an example, the second layer section is ring-shaped and the first conductor interface extends around the first opening in a circumferentially closed manner. In this context, ring-shaped is to be understood as being shaped like a fully closed ring. The ring may have a polygonal, e.g., rectangular, circular or elliptical geometry. This offers the possibility to connect the first conductor to the first conductor interface using the full circumference of the first conductor. This has the effect, that a comparatively big electrically conducting connection area is provided. This makes the electromagnetic filter assembly suitable for being connected to a first conductor which is transmitting comparatively high currents.

In another example, the first conductor interface just extends around a portion of the first opening. Also in this configuration, a sufficiently big electrically conducting connection area may be provided.

In an example, the base plate has a second opening being configured to be penetrated by a second conductor from which the electromagnetic interference at least partially originates. The base plate comprises an electrically conductive third layer section, wherein the third layer section comprises a second conductor interface configured to connect the third layer section to the second conductor in an electrically conductive manner. The first layer section and the third layer section are capacitively coupled via at least two discrete capacitor elements. Thus, the electromagnetic filter assembly is configured to be used in connection with two conductors, i.e., the first conductor and the second conductor, from which an electromagnetic interference at least partially originates. In a case in which the electromagnetic filter assembly is used in connection with a DC circuit, the first conductor may be connected to a DC+ pole and the second conductor may be connected to a DC− pole. In this example, both the first conductor and the second conductor may be capacitively coupled to the shielding via the respective first conductor interface and second conductor interface and the discrete capacitor elements. Consequently, an electromagnetic interference originating from the first conductor and/or the second conductor may be efficiently and effectively attenuated. All effects and advantages that have been mentioned in connection with the first conductor also apply to the second conductor. It is noted that the term “third” is just used for the ease of explanation. A number of layer sections is not implied.

In another example, the base plate has a second opening being configured to receive a second conductor from which the electromagnetic interference at least partially originates. The base plate comprises an electrically conductive third layer section, wherein the third layer section comprises a second conductor interface configured to connect the third layer section to the second conductor in an electrically conductive manner. The base plate may additionally comprise an electrically conductive fourth layer section, wherein the fourth layer section comprises a shielding interface configured to connect the fourth layer section to the shielding in an electrically conductive manner. The third layer section and the fourth layer section are arranged at least partially opposite each other such that the third layer section and the fourth layer section form a capacitor. Additionally or alternatively, the third layer section and the fourth layer section are capacitively coupled via at least two discrete capacitor elements. As before, the term “fourth” is just used for the ease of explanation. A number of layer sections is not implied. In the present example, at least two discrete capacitor elements are coupling the first conductor interface, to which the first conductor may be connected, and the shielding interface. To this end, the first layer section is provided. Additionally, at least two discrete capacitor elements are coupling the second conductor interface, to which the second conductor may be connected, and the shielding interface. To this end, the fourth layer section is provided. Thus, in total, at least four discrete conductor elements are provided. In this context, the first layer section and the fourth layer section may be arranged on opposite ends of the base plate. Consequently, also in this configuration, an electromagnetic interference originating from the first conductor and/or from the second conductor may be efficiently and effectively attenuated.

In examples in which the base plate comprises a second layer section and a third layer section being configured to be connected to a first conductor and a second conductor respectively, the second layer section and the third layer section can be placed in parallel with only an isolating (dielectric) layer in between. Consequently, a differential capacitance is formed between these layer sections. Such a capacitance attenuates differential mode disturbances between the second layer section and the third layer section and the corresponding conductors.

In an example, the at least two discrete capacitor elements are evenly distributed around a circumference of the second opening. Also in this configuration, the same effects and advantages apply that have already been explained in connection with the at least two discrete capacitor elements that are evenly distributed around the circumference of the first opening. Reference is made to the above explanations.

In an example, the third layer section is ring-shaped and the second conductor interface extends around the opening in a circumferentially closed manner. Again, ring-shaped is to be understood as being shaped like a fully closed ring. This offers the possibility to connect the second conductor to the second conductor interface using the full circumference of the second conductor. This has the effect, that a comparatively big electrically conducting connection area is provided. This makes the electromagnetic filter assembly suitable for being connected to a second conductor which is transmitting comparatively high currents.

In an example, the shielding interface comprises a plurality of shielding interface sections being spaced from one another. In this context, the plurality of shielding interface sections may be distributed along an edge of the base plate. In any case, a plurality of shielding interface sections is provided such that the electric connection to the shielding is established at different locations. Additionally, a conductive area of the shielding interface is formed by the sum of the conductive areas of the plurality of shielding interface sections. Consequently, a comparatively big conductive area may be provided such that the connection to the shielding may have a comparatively low resistance and low impedance. As a result thereof, the electromagnetic filter assembly has a good filter performance.

In an example, each shielding interface section at least partially extends around a respective shielding connection hole being configured to receive a shielding connection bolt. In other words, the shielding interface is configured to be connected to a shielding via shielding connection bolt. These shielding connection bolts are to be placed in respective shielding connection holes. Thereby, a highly reliable shielding connection may be established in the electric sense. Additionally, the shielding connection bolt may reliably connect the electromagnetic filter assembly to a shielding in a mechanical sense.

In an example, the shielding interface comprises at least one shielding interface section extending along an edge of the first layer section. Such a shielding interface section may be described as line-shaped. The line may have corners and/or curves. The shielding interface section may also fully cover all exterior edges of the first layer section. Consequently, a comparatively big conductive area may be provided such that the connection to the shielding may have a comparatively low resistance and low impedance. As a result thereof, the electromagnetic filter assembly has a good filter performance.

It is noted that even though in the above examples, an electromagnetic filter assembly for one or two conductors has been explained in detail, it is also possible to configure the electromagnetic filter assembly such that it is adapted for being used in combination with three or more conductors, especially in combination with three, four or five conductors.

It is additionally noted that even though in the above examples, two to four electrically conductive layer sections have been described as forming part of the base plate, the base plate can also comprise more than four electrically conductive layer sections.

According to a second aspect, there is provided a feedthrough assembly. The feedthrough assembly comprises an electromagnetic filter assembly according to the present disclosure and a first conductor. The first conductor extends through the first opening and is connected to the second layer section in an electrically conductive manner via the first conductor interface. The first conductor may be electrically connected to the first conductor interface using its entire circumference. Consequently, an electromagnetic interference originating at least partly from the first conductor may be attenuated in a reliable and effective manner.

In an example, the feedthrough assembly also comprises a second conductor which is connected to the second conductor interface in an electrically can ducted manner. The second conductor may be electrically connected to the second conductor interface using its entire circumference. Consequently, an electromagnetic interference originating at least partly from the second conductor may be attenuated in a reliable and effective manner.

According to a third aspect, there is provided an enclosure assembly for at least one electric component. The enclosure assembly comprises an electromagnetic filter assembly according to the present disclosure and an enclosure having at least one wall. The wall has a wall opening being at least partially covered by the base plate of the electromagnetic filter assembly. The first layer section of the electromagnetic filter assembly is connected to the wall in an electrically conductive manner via the shielding interface. It is understood that at least the portion of the wall to which the first layer section is connected, is electrically conductive. In another example, the entire wall is electrically conductive. In a further example, the entire enclosure is electrically conductive. Thus, electromagnetic interferences originating at least partly from a conductor which extends through the wall opening and the first opening of the electromagnetic filter assembly may be attenuated in an effective and reliable manner. Consequently, the electric component being arranged in the enclosure assembly may be efficiently and effectively protected from electromagnetic interferences resulting from an outside of the enclosure assembly. At the same time, an environment or outside of the enclosure assembly may be protected from electromagnetic interferences resulting from the electric component inside the enclosure assembly.

In an example, the enclosure assembly is an electromagnetic shielding assembly that is configured to electromagnetically separate an interior of the enclosure assembly from an exterior of the enclosure assembly. Optionally, the enclosure assembly may also separate the interior and the exterior in a mechanical and thermal sense. In other words, the enclosure assembly may also be configured to mechanically protect the interior of the enclosure assembly from mechanical influences resulting from the exterior of the enclosure assembly and vice versa. Moreover, the enclosure assembly may be configured to thermally protect the interior of the enclosure assembly from thermal influences resulting from the exterior of the enclosure assembly and vice versa.

In a case in which the enclosure assembly is an electromagnetic shielding assembly, the enclosure may be called a shielding enclosure.

In an example, the enclosure assembly is configured to enclose an inverter unit, i.e., a DC-AC converter unit. Additionally or alternatively, the enclosure assembly may be configured to enclose an AC-DC converter, a DC-DC converter unit and/or an AC-AC converter unit.

In an example, the enclosure assembly further comprises a first conductor, wherein the first conductor extends through the first opening and is connected to the second layer section in an electrically conductive manner via the first conductor interface. In other words, the enclosure assembly comprises the feedthrough assembly according to the present disclosure. In this context, all the effects and advantages that have already been mentioned in connection with the feedthrough assembly and/or the electromagnetic filter assembly apply mutatis mutandis.

According to a fourth aspect, there is provided a vehicle comprising an enclosure assembly according to the present disclosure. The enclosure assembly forms part of a drivetrain of the vehicle. As has already been mentioned, inside the enclosure assembly, an inverter unit, i.e., a DC-AC converter unit, an AC-DC converter unit, a DC-DC converter unit or an AC-AC converter unit may be located. Consequently, the drivetrain of the vehicle or more specifically the mentioned components of the drivetrain, are reliably protected from electromagnetic interferences resulting from an environment of the drivetrain. At the same time, the environment of the drivetrain is reliably protected from electromagnetic interferences resulting from the drivetrain.

It is noted that in a case in which the filter assembly according to the present disclosure, the feedthrough assembly and/or the enclosure assembly are used in a vehicle, the first conductor and/or the second conductor may be subject to comparatively high currents, voltages and/or power. For example, the first conductor and/or the second conductor may be subject to 60 V direct current or more. In another example, the first conductor and/or the second conductor may be subject to at least 25 V (root mean square value) alternating current.

In these kinds of applications, the first conductor and/or the second conductor may be used for power supply.

It should be noted that the above examples may be combined with each other irrespective of the aspect involved.

These and other aspects of the present disclosure will become apparent from and elucidated with reference to the examples described hereinafter.

### BRIEF DESCRIPTION OF DRAWINGS

Examples of the disclosure will be described in the following with reference to the drawings.

FIG. 1 shows a vehicle according to the present disclosure having a drivetrain with an enclosure assembly according to the present disclosure, wherein the enclosure assembly comprises a feedthrough assembly according to the present disclosure with an electromagnetic filter assembly according to the present disclosure,

FIG. 2 shows a detail of the enclosure assembly of FIG. 1 in a sectional view,

FIG. 3 shows a detail of the enclosure assembly of FIG. 1 in a perspective view from an inside of the enclosure assembly,

FIG. 4 shows the detail of FIG. 3 along a direction IV in FIG. 3,

FIG. 5 shows another example of an enclosure assembly according to the present disclosure having a feedthrough assembly according to another example of the present disclosure with an electromagnetic filter assembly according to another example of the present disclosure in a sectional view,

FIG. 6 shows the enclosure assembly of FIG. 5 along direction VI in FIG. 5,

FIG. 7 shows a further example of an enclosure assembly according to the present disclosure having a feedthrough assembly according to a further example of the present disclosure with an electromagnetic filter assembly according to a further example of the present disclosure in a sectional view,

FIG. 8 shows the enclosure assembly of FIG. 7 along direction VIII in FIG. 7,

FIG. 9 shows the feedthrough assembly of FIG. 7 along direction IX in FIG. 7,

FIG. 10 shows a further example of an enclosure assembly according to the present disclosure having a feedthrough assembly according to a further example of the present disclosure with an electromagnetic filter assembly according to a further example of the present disclosure in a sectional, schematic view,

FIG. 11 shows the enclosure assembly of FIG. 10 in a perspective view, and

FIG. 12 shows the enclosure assembly of FIG. 11 in a top view.

### DETAILED DESCRIPTION

The Figures are merely schematic representations and serve only to illustrate examples of the disclosure. Identical or equivalent elements are in principle provided with the same reference signs.

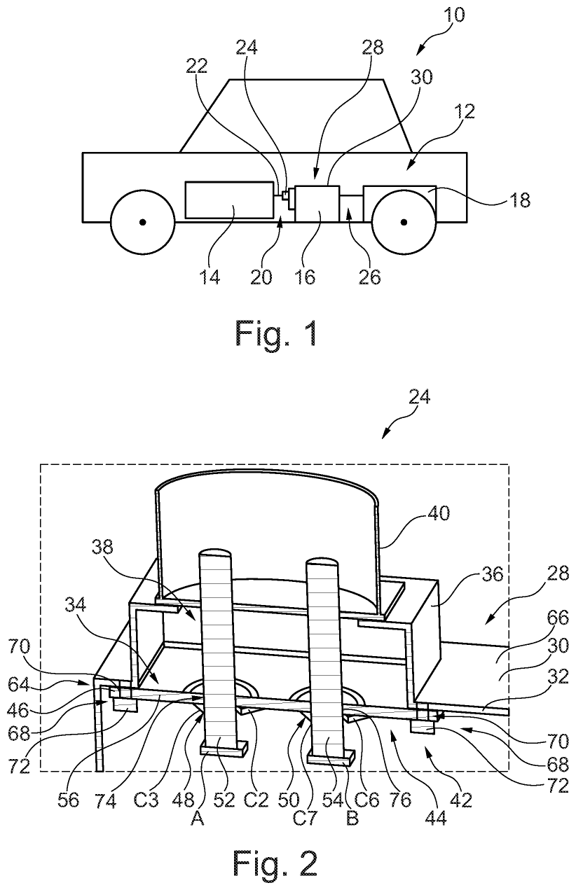

FIG. 1 shows a vehicle 10 which in the present example is a battery electric vehicle.

The vehicle 10 has a drivetrain 12 which comprises a battery unit 14, an inverter unit 16 and an electric motor unit 18.

The battery unit 12 and the inverter unit 16 are electrically connected by a first electric connection 20. In the present example, the first electric connection 20 comprises a cable 22 which is mechanically and electrically connected to a connector 24 of the inverter unit 16.

The inverter unit 16 and the electric motor unit 18 are electrically connected by a second electric connection 26.

The inverter unit 16 comprises an enclosure assembly 28. Consequently, the enclosure assembly 28 also forms part of the drivetrain 12.

The enclosure assembly 28 comprises an enclosure 30.

In the present example, the enclosure 30 is configured to house the components of the inverter unit 16 which are configured to transform a 2-phase DC current being provided by the battery unit 14 into a three-phase AC current for operating the electric motor unit 18. More precisely, the enclosure 30 is configured to separate these components from an environment of the inverter unit 16 in a mechanical, thermal and electromagnetic sense. The separation in an electromagnetic sense may also be called an electromagnetic shielding which is performed by the enclosure 30.

It is noted that the components for transforming the 2-phase DC current into a 3-phase AC current are not shown in the Figures for the ease of representation.

Details of the enclosure assembly 28 can be seen in FIGS. 2 to 4.

The enclosure 30 comprises several walls 32 which delimit the enclosure 30.

The wall 32 which is oriented towards the battery unit 14 comprises a wall opening 34.

On an outside of the enclosure 30, a projection element 36 is mounted to the wall 32 such that it covers the wall opening 34. On an end of the projection element 36 which is arranged opposite the wall opening 34, a projection element opening 38 is provided. This projection element opening 38 is covered by a housing 40 of the connector 24.

On an inside of the enclosure 30, a feedthrough assembly 42 is mounted to the wall 32.

The feedthrough assembly 42 comprises an electromagnetic filter assembly 44 for attenuating electromagnetic interferences. The electromagnetic filter assembly 44 has a base plate 46 with a first opening 48 and a second opening 50.

The base plate 46 fully covers the wall opening 34.

Moreover, the feedthrough assembly 42 comprises a first conductor 52 and a second conductor 54.

Both the first conductor 52 and the second conductor 54 are formed by conduction rods which extend from an interior of the enclosure 30 through the respective first opening 48 or second opening 50, through the interior of the projection element 36 and through the projection element opening 38 such that an end of the first conductor 52 and an end of the second conductor 54 protrude into the housing 40 of the connector 24.

As has been explained before, the battery unit 14 can be connected to the inverter unit 16 via the connector 24. Consequently, the first conductor 52 may also be called a DC+ connector and the second conductor 54 may be called a DC− connector or vice versa.

Inside the enclosure, two bus bars A, B are connected to the first conductor 52 and the second conductor 54 respectively.

The first conductor 52 and the second conductor 54 extend in parallel.

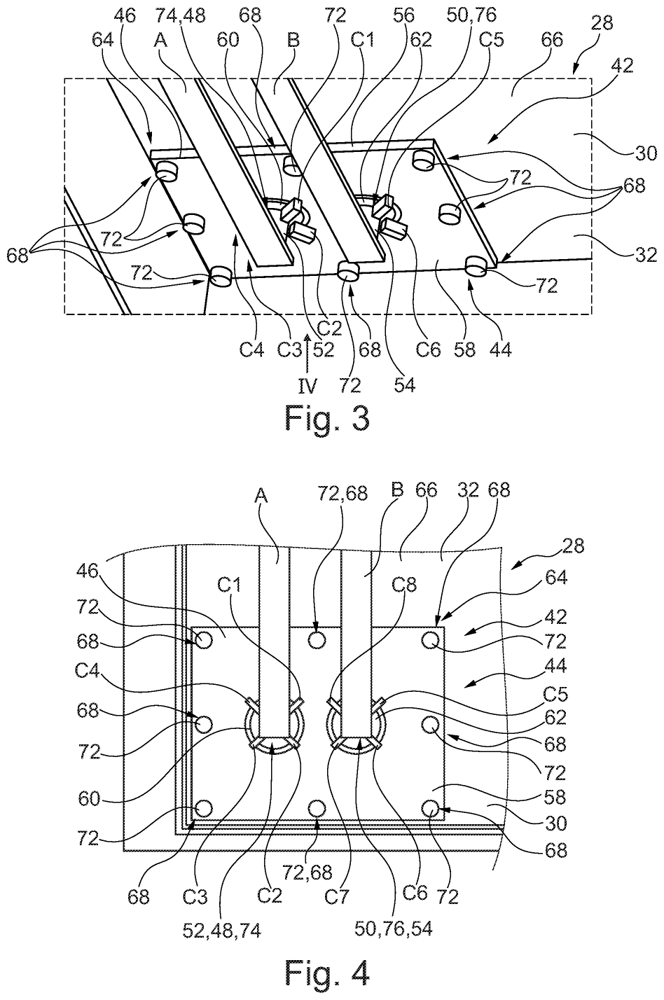

The electromagnetic filter assembly 44 may be seen best in FIGS. 3 and 4.

As has already been mentioned, the electromagnetic filter assembly 44 comprises the base plate 46 having the first opening 48 which is configured to be penetrated by the first conductor 52 and the second opening 50 being configured to be penetrated by the second conductor 54.

In the present example, it is assumed, that the electromagnetic interference at least partially originates from the first conductor 52 and the second conductor 54.

The base plate 46 comprises a non-conductive carrier layer 56. In the present example, the non-conductive carrier layer 56 substantially covers the full area of the base plate 46 except for the first opening 48 and the second opening 50.

Moreover, the base plate 46 comprises an electrically conductive first layer section 58, an electrically conductive second layer section 60 and an electrically conductive third layer section 62. The first layer section 58, the second layer section 60 and the third layer section 62 are electrically isolated from one another.

Beyond that, the first layer section 58, the second layer section 60 and the third layer section 62 are arranged in a common plane.

The first layer section 58 comprises a shielding interface 64 which is configured to connect the first layer section 58 to a shielding 66 in an electrically conductive manner. In the present example, the enclosure 30 forms the shielding 66.

The shielding interface 64 comprises a plurality of shielding interface sections 68 being spaced from one another. A total of eight shielding interface section 68 is provided. Each shielding interface section 68 extends around a respective shielding connection hole 70 being configured to receive a shielding connection bolt 72.

In the present example, thus, the first layer section 58 is connected to the shielding 66 in an electrically conductive manner via a total of eight connection bolts 72.

It is noted that as an alternative to connecting the first layer section 58 and the shielding 66 via shielding connection bolts 72, the shielding interface 64 may also comprise at least one shielding interface section 68 extending along an edge of the first layer section 58, i.e., an elongated shielding interface section 68 such as a soldered joint.

The second layer section 60 comprises a first conductor interface 74 which is configured to connect the second layer section 60 to the first conductor 52 in an electrically conductive manner.

The second layer section 60 is ring-shaped and the first conductor interface 74 extends around the first opening 48 in a circumferentially closed manner.

Moreover, in the present example, the first conductor 52 is connected to the first conductor interface 74 by a press fit such that the first conductor 52 is connected to the first conductor interface 74 substantially over its entire circumference. As an alternative to the press fit, a solder joint may be provided.

In the present example, in order to provide the filtering effect, the second layer section 60 is capacitively coupled to the first layer section 58 via a total of four discrete capacitor elements C1, C2, C3, C4. The capacitor elements C1, C2, C3, C4 are evenly distributed around a circumference of the first opening 48 and, thus, also around a circumference of the first conductor 52.

The third layer section 62 comprises a second conductor interface 76 which is configured to connect the third layer section 62 to the second conductor 54 in an electrically conductive manner.

The third layer section 62 is ring-shaped and the second conductor interface 76 extends around the second opening 50 in a circumferentially closed manner.

Moreover, in the present example, the second conductor 54 is connected to the second conductor interface 76 by a press fit such that the second conductor 54 is connected to the second conductor interface 76 substantially over its entire circumference. As an alternative to the press fit, a solder joint may be provided.

In the present example, in order to provide the filtering effect, the third layer section 62 is capacitively coupled to the first layer section 58 via a total of four discrete capacitor elements C5, C6, C7, C8. The capacitor elements C5, C6, C7, C8 are evenly distributed around a circumference of the second opening 50 and, thus, also around a circumference of the second conductor 54 (see especially FIG. 4).

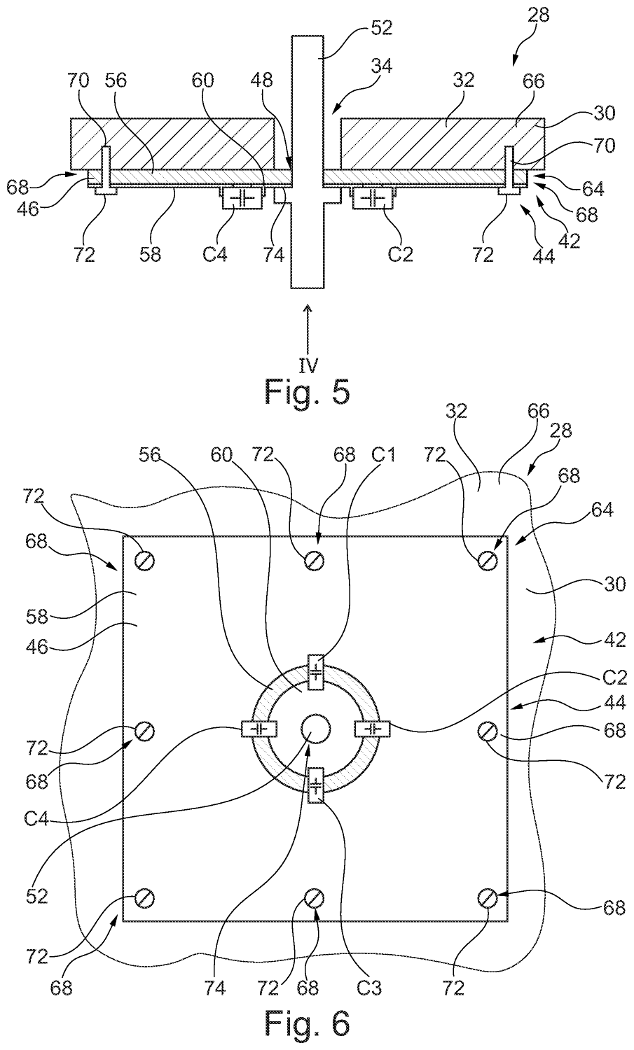

FIGS. 5 and 6 show another example of the enclosure assembly 28.

In the following, only the difference is with respect to the example as explained in connection with FIGS. 2 to 4 will be explained. Same or corresponding elements will be provided with the same reference signs.

In the example of FIGS. 5 and 6, the enclosure 30 is not provided with a projection element. Neither is the enclosure 30 equipped with a connector.

A further difference relates to the fact, that in the example of FIGS. 5 and 6 only one conductor is provided. For ease of explanation, this conductor will be referred to as the first conductor 52 in the following. However, it is obvious that the conductor could also be designated as a second conductor 54.

Beyond that, especially as far as the electrically conductive first layer section 58 and the electrically conductive second layer section 60 and the discrete capacitor elements C1, C2, C3, C4 are concerned, reference is made to the above explanations.

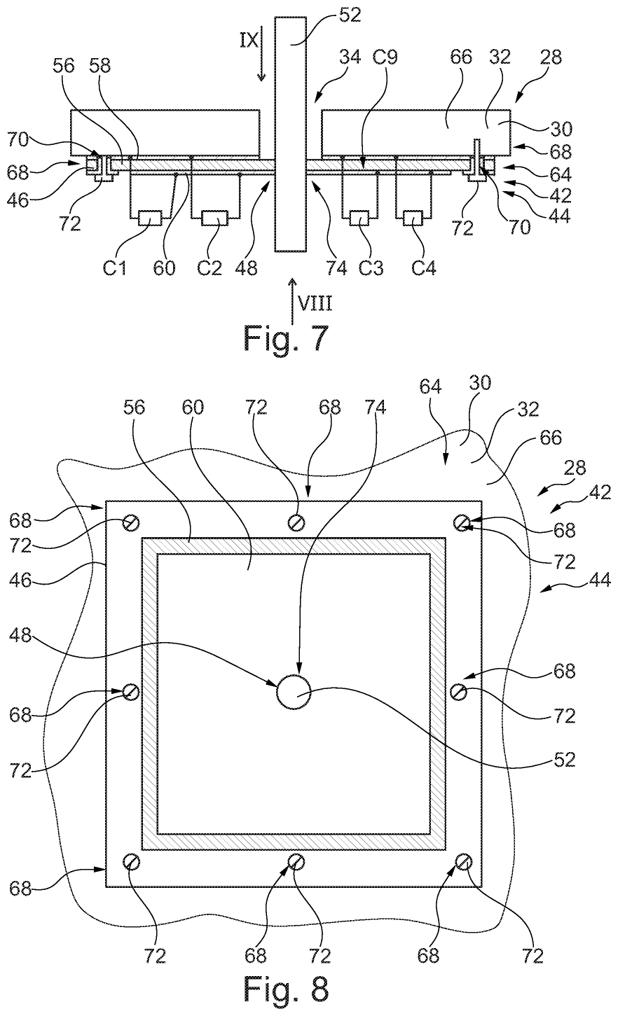

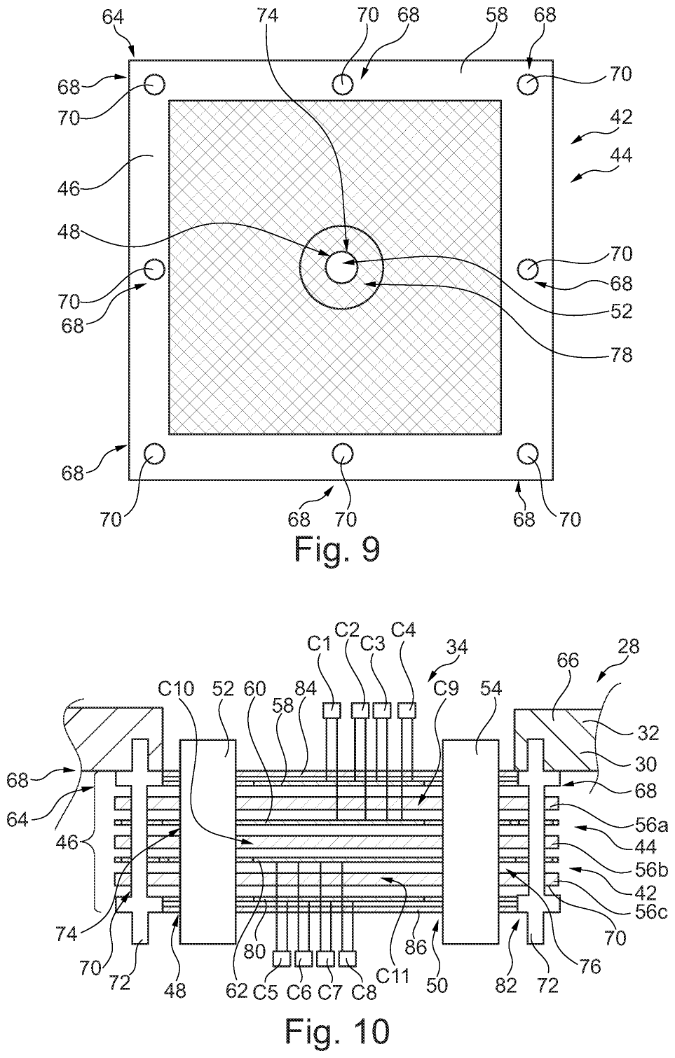

FIGS. 7 to 9 show a further example of the enclosure assembly 28, wherein FIG. 9 only shows the feedthrough assembly 42 without the enclosure 30.

In the following, only the difference is with respect to the previous examples will be explained. Same or corresponding elements will be designated with the same reference signs.

The enclosure 30 in the example of FIGS. 7 to 9 is the same as in the example of FIGS. 5 and 6.

Moreover, also in the example of FIGS. 7 to 9, only one conductor is provided. This conductor will be designated as a first conductor 52. However, it is obvious that the conductor could also be designated as a second conductor 54.

In contrast to the previous examples, now the first layer section 58 comprising the shielding interface 64 and the second layer section 60 comprising the first conductor interface 74 are arranged opposite each other. More precisely, the first layer section 58 and the second layer section 60 are arranged on opposite sides of the carrier layer 56.

Consequently, the first layer section 58 and the second layer section 60 form a capacitor C9.

The capacitor C9 comes in addition to the capacitor elements C1, C2, C3, C4.

For reasons of better visibility of the capacitor C9, capacitor elements C1, C2, C3, C4 have been represented in a schematic manner only in FIG. 7. In FIGS. 8 and 9, the capacitor elements C1, C2, C3, C4 are not represented at all.

Since the first layer section 58 and the second layer section 60 form electrodes of the capacitor C9, it is important that the first layer section 58 only is conductively coupled with the enclosure 30 or the shielding 66 via the shielding interface 64.

In other words, a middle part of the first layer section 58 must be isolated with respect to the enclosure 30. To this end, an isolation layer 78 is provided on the first layer section 58 such that it is interposed between the first layer section 58 and the enclosure 30 when the electromagnetic filter assembly 44 is mounted to the enclosure 30.

FIGS. 10 to 12 show a further example of the enclosure assembly 28.

As before, only the differences with respect to the previous examples will be explained. Same or corresponding elements will be provided with the same reference signs.

FIG. 10 comprises a schematic, sectional representation of the enclosure assembly 28.

As in the example of FIGS. 2 to 4, two conductors, i.e., a first conductor 52 and a second conductor 54, are provided.

However, in contrast to the preceding examples, now a total of three non-conductive carrier layers 56 is provided. In FIG. 10, these carrier layers 56 are designated as carrier layers 56a, 56b, 56c.

The electrically conductive first layer section 58 is arranged on top of carrier layer 56a. As before, the first layer section 58 is connected to the enclosure 30 or shielding 66 by a plurality of shielding connection bolts 72.

Also as in the previous examples, the first conductor 52 is connected to the electrically conductive second layer section 60 in an electrically conductive manner.

The electrically conductive second layer section 60 is arranged below the carrier layer 56a.

Consequently, the first layer section 58 and the second layer section 60 form the capacitor C9 as has already been explained in connection with the example of FIG. 7. The carrier layer 56a forms a dielectric of the capacitor C9.

Below the second layer section 60, carrier layer 56b is arranged.

Below carrier layer 56b, there is provided the third layer section 62. As before, the third layer section 62 is connected to the second conductor 54 in an electrically conductive manner.

Consequently, in the present example, also the second layer section 60 and the third layer section 62 form a capacitor C10. Carrier layer 56b is a dielectric of this capacitor C10.

Below the third layer section 62, there is arranged carrier layer 56c.

Below carrier layer 56c, a fourth electrically conductive layer section 80 is arranged.

The fourth electrically conductive layer section 80 comprises a shielding interface 82 configured to connect the fourth layer section 80 to the shielding 66 in an electrically conductive manner. In the present example, the fourth electrically conductive layer 80 is connected to the enclosure 30 or shielding 66 by a plurality of shielding connection bolts 72.

The third layer section 62 and the fourth layer section 80 are arranged opposite each other and, thus, the third layer section 62 and the fourth layer section 80 from a capacitor C11.

In the representation of FIG. 10, the base plate 46 additionally comprises a top protection layer 84 and a bottom protection layer 86. These layers do not have a filtering functionality.

Beyond that, the first layer section 58 and the second layer section 60 are capacitively coupled by a total of four discrete capacitor elements C1, C2, C3, C4 which are illustrated in a schematic manner in FIG. 10.

Moreover, also the third layer section 62 and the fourth layer section 80 are capacitively coupled by a total of four discrete capacitor elements C5, C6, C7, C8 which are illustrated in a schematic manner in FIG. 10.

Optionally, the second layer section 60 and the third layer section 62 may be capacitively coupled by one or more discrete capacitor elements. Using such discrete capacitor elements, differential disturbances between the first conductor 52 and the second conductor 54 may be attenuated. These discrete capacitor elements are not shown in the Figures for the ease of representation.

Consequently, the example of FIGS. 10 to 12 can be seen as a combination of the example of FIGS. 2 to 4 and the example of FIGS. 7 to 9. Reference is specifically made to the above explanations.

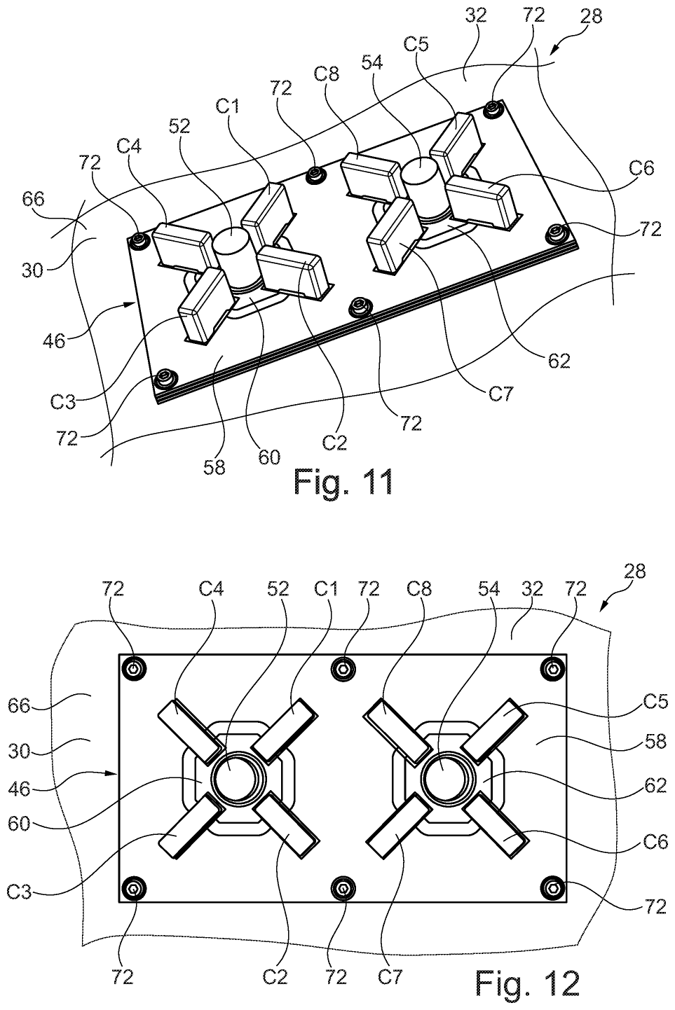

FIGS. 11 and 12 show a non-sectional representation of the enclosure assembly 28. As can be seen from the Figures, capacitor elements C1, C2, C3, C4 are evenly distributed around the circumference of the first opening 48 and capacitor elements C5, C6, C7, C8 are evenly distributed around the circumference of the second opening 50.

Other variations to the disclosed examples can be understood and effected by those skilled in the art in practicing the claimed disclosure, from the study of the drawings, the disclosure, and the appended claims. In the claims the word “comprising” does not exclude other elements or steps and the indefinite article “a” or “an” does not exclude a plurality. A single processor or other unit may fulfill the functions of several items or steps recited in the claims. The mere fact that certain measures are recited in mutually different dependent claims does not indicate that a combination of these measures cannot be used to advantage. A computer program may be stored/distributed on a suitable medium such as an optical storage medium or a solid-state medium supplied together with or as part of other hardware, but may also be distributed in other forms, such as via the Internet or other wired or wireless telecommunication systems. Any reference signs in the claims should not be construed as limiting the scope of the claims.

### LIST OF REFERENCE SIGNS

10 vehicle
12 drivetrain
14 battery unit
16 inverter unit
18 electric motor unit
20 first electric connection
22 cable
24 connector
26 second electric connection
28 enclosure assembly
30 enclosure
32 wall
34 wall opening
36 projection element
38 projection element opening
40 housing
42 feedthrough assembly
44 electromagnetic filter assembly
46 base plate
48 first opening
50 second opening
52 first conductor
54 second conductor
56 non-conductive carrier layer
58 electrically conductive first layer section
60 electrically conductive second layer section
62 electrically conductive third layer section
64 shielding interface
66 shielding
68 shielding interface section
70 shielding connection hole
72 shielding connection bolt
74 first conductor interface
76 second conductor interface
78 isolation layer
80 electrically conductive fourth layer section
82 shielding interface
84 top protection layer
86 bottom protection layer
A bus bar
B bus bar
C1 to C8 discrete capacitor element
C9 capacitor
C10 capacitor
C11 capacitor

What is claimed is:

1. An electromagnetic filter assembly for attenuating electromagnetic interferences, comprising:
a base plate comprising a first opening configured to be penetrated by a first conductor from which an electromagnetic interference at least partially originates,
wherein the base plate comprises an electrically non-conductive carrier layer, an electrically conductive first layer section, and an electrically conductive second layer section,
wherein the first layer section comprises a shielding interface configured to connect the first layer section to a shielding in an electrically conductive manner,
wherein the second layer section comprises a first conductor interface configured to connect the second layer section to the first conductor in an electrically conductive manner, and
wherein the first layer section and the second layer section are capacitively coupled via at least two first discrete capacitor elements.

2. The electromagnetic filter assembly of claim 1, wherein the first layer section and the second layer section are arranged in a common plane.

3. The electromagnetic filter assembly of claim 1, wherein the first layer section and the second layer section are arranged at least partially opposite each other such that the first layer section and the second layer section form a capacitor.

4. The electromagnetic filter assembly of claim 1, wherein the at least two first discrete capacitor elements are evenly distributed around a circumference of the first opening.

5. The electromagnetic filter assembly of claim 1, wherein the second layer section is ring-shaped and wherein the first conductor interface extends around the first opening in a circumferentially closed manner.

6. The electromagnetic filter assembly of claim 1,
wherein the base plate comprises a second opening configured to be penetrated by a second conductor from which the electromagnetic interference at least partially originates,
wherein the base plate comprises an electrically conductive third layer section,
wherein the third layer section comprises a second conductor interface configured to connect the third layer section to the second conductor in an electrically conductive manner, and
wherein the first layer section and the third layer section are capacitively coupled via at least two second discrete capacitor elements.

7. The electromagnetic filter assembly of claim 6, wherein the at least two second discrete capacitor elements are evenly distributed around a circumference of the second opening.

8. The electromagnetic filter assembly of claim 1,
wherein the base plate comprises a second opening configured to receive a second conductor from which the electromagnetic interference at least partially originates,
wherein the base plate comprises an electrically conductive third layer section,
wherein the third layer section comprises a second conductor interface configured to connect the third layer section to the second conductor in an electrically conductive manner,
wherein the base plate comprises an electrically conductive fourth layer section,
wherein the fourth layer section comprises a shielding interface configured to connect the fourth layer section to the shielding in an electrically conductive manner, and
wherein the third layer section and the fourth layer section are arranged at least partially opposite each other such that the third layer section and the fourth layer section form a capacitor or wherein the third layer section and the fourth layer section are capacitively coupled via at least two second discrete capacitor elements.

9. The electromagnetic filter assembly of claim 8, wherein the at least two second discrete capacitor elements are evenly distributed around a circumference of the second opening.

10. The electromagnetic filter assembly of claim 1, wherein the shielding interface comprises a plurality of shielding interface sections spaced from one another.

11. The electromagnetic filter assembly of claim 10, wherein each shielding interface section at least partially extends around a respective shielding connection hole configured to receive a shielding connection bolt.

12. The electromagnetic filter assembly of claim 1, wherein the shielding interface comprises at least one shielding interface section extending along an edge of the first layer section.

13. A feedthrough assembly, comprising:
an electromagnetic filter assembly for attenuating electromagnetic interferences, the electromagnetic filter assembly comprising:
a base plate comprising a first opening configured to be penetrated by a first conductor from which an electromagnetic interference at least partially originates,
wherein the base plate comprises an electrically non-conductive carrier layer, an electrically conductive first layer section, and an electrically conductive second layer section,
wherein the first layer section comprises a shielding interface configured to connect the first layer section to a shielding in an electrically conductive manner,
wherein the second layer section comprises a first conductor interface configured to connect the second layer section to the first conductor in an electrically conductive manner, and
wherein the first layer section and the second layer section are capacitively coupled via at least two discrete capacitor elements; and
a first conductor, wherein the first conductor extends through the first opening and is connected to the second layer section in an electrically conductive manner via the first conductor interface.

14. An enclosure assembly for at least one electric component, comprising:
an electromagnetic filter assembly for attenuating electromagnetic interferences, the electromagnetic filter assembly comprising:
a base plate comprising a first opening configured to be penetrated by a first conductor from which an electromagnetic interference at least partially originates,
wherein the base plate comprises an electrically non-conductive carrier layer, an electrically conductive first layer section, and an electrically conductive second layer section,
wherein the first layer section comprises a shielding interface configured to connect the first layer section to a shielding in an electrically conductive manner,
wherein the second layer section comprises a first conductor interface configured to connect the second layer section to the first conductor in an electrically conductive manner, and
wherein the first layer section and the second layer section are capacitively coupled via at least two discrete capacitor elements; and
an enclosure comprising at least one wall,
wherein the wall comprises a wall opening at least partially covered by the base plate of the electromagnetic filter assembly, and
wherein the first layer section is connected to the wall in an electrically conductive manner via the shielding interface.

15. The enclosure assembly of claim 14, further comprising:
a first conductor, wherein the first conductor extends through the first opening and is connected to the second layer section in an electrically conductive manner via the first conductor interface.

16. The enclosure assembly of claim 14, wherein the enclosure assembly forms part of a drivetrain of a vehicle.

17. The enclosure assembly of claim 14, wherein the first layer section and the second layer section are arranged in a common plane.

18. The enclosure assembly of claim 14, wherein the first layer section and the second layer section are arranged at least partially opposite each other such that the first layer section and the second layer section form a capacitor.

19. The enclosure assembly of claim 14, wherein the at least two discrete capacitor elements are evenly distributed around a circumference of the first opening.

20. The enclosure assembly of claim 14, wherein the second layer section is ring-shaped and wherein the first conductor interface extends around the first opening in a circumferentially closed manner.
